(19) United States
(12) Patent Application Publication
(10) Pub. No.: US 2012/0318326 A1
(43) Pub. Date: Dec. 20, 2012

(54) THIN FILM SOLAR CELL MODULE AND MANUFACTURING METHOD THEREOF

(75) Inventors: Yusuke Nishikawa, Tokyo (JP); Yasutoshi Yashiki, Tokyo (JP)

(73) Assignee: Mitsubishi Electric Corporation, Tokyo (JP)

(21) Appl. No.: 13/581,868

(22) PCT Filed: Feb. 25, 2011
(86) PCT No.: PCT/JP2011/001109

§ 371 Date: Aug. 30, 2012

(30) Foreign Application Priority Data
Mar. 2, 2010 (JP) 2010-045243

(51) Int. Cl. H01L 31/05; H01L 31/18

(52) U.S. Cl. 136/246; 438/69; 257/E31.124

(57) ABSTRACT

A thin film solar cell module including a plurality of cells in which a transparent electrode, a photoelectric conversion layer, and a rear surface electrode are stacked in this order includes a first photoelectric conversion layer separation trench and a rear surface electrode separation trench in which the photoelectric conversion layer is removed between a cell connection apertural area and a transparent electrode separation trench and between the cell connection apertural area and a rear surface electrode separation trench, and white reflection materials having an insulation property are formed at the inside of the trenches. The structure improves light use efficiency of thin film solar cells, and achieves thin film solar cell modules easily manufacturable.

### TECHNICAL FIELD

The present invention relates to thin film solar cell modules and methods of manufacturing the same.

### BACKGROUND ART

As a solar cell module for directly converting solar energy into electric energy, there is known a thin film solar cell module in which a plurality of photoelectric conversion cells consisting of thin films are electrically connected in series on a substrate. The module is manufactured by stacking a front surface electrode layer, a semiconductor photoelectric conversion layer, and a rear surface electrode, forming trenches in these layers to separate them into unit cells, and connecting the cells electrically with each other by utilizing the trenches or the like.

In Patent Document 1, for example, a module is manufactured by a procedure described below. First, layers from the rear surface electrode through the front surface electrode are separated into unit cells by a first separation trench. Next, a second separation trench is formed to separate layers from the rear surface electrode through the photoelectric conversion layer. After that, along with filling the first separation trench and the second separation trench with an insulation film, a connection trench is formed in a portion of the insulation film to expose the rear surface electrode. And then, between the first separation trench and the second separation trench, another connection trench is formed by removing layers from the insulation film through the photoelectric conversion layer. Finally, along with connecting the adjacent unit cells by forming on the insulation film a conductive material member for connecting the connection trenches, a third separation trench is formed to separate the conductive material member between the unit cells. Since the connection trench and the photoelectric conversion layer are separated by the first separation trench and the second separation trench, leakage in a transverse direction is prevented.

In Patent Document 2, a transparent front surface electrode, a photoelectric conversion layer, and a rear surface electrode are stacked on a translucent insulation substrate, and a portion is formed in which the photoelectric conversion layer and the rear surface electrode are removed. By forming white paint or a reflection film on the portion, incident light which penetrates without passing through the photoelectric conversion layer is guided to the photoelectric conversion layer by the white paint or the reflection film, thereby improving incident light use efficiency.

### PRIOR ART DOCUMENT

### Patent Document

Patent Document 1: Japanese Unexamined Patent Application Publication No. 2004-260013

Patent Document 2: Japanese Unexamined Patent Application Publication No. 2004-022961

### SUMMARY OF INVENTION

### Problem That the Invention is to Solve

In such a thin film solar cell module structure according to Patent Document 1, there exists a non-power generation area which does not contribute to solar power generation at a cell connecting portion between the cells. The separation trench to separate the layers into the unit cells, by removing the photoelectric conversion layer and the rear surface electrode, is also a non-power generation area. In the separation trench, incident light from a translucent substrate passes toward the rear surface without entering the photoelectric conversion layer, and incident light which has once entered the photoelectric conversion layer and has not been absorbed therein passes toward the rear surface after emitted to the separation trench.

In Patent Document 2, while a reflection material member is formed on the portion in which the photoelectric conversion layer and the rear surface electrode are removed, the portion is limited only to one side surface of the photoelectric conversion layer in the power generation area, and the other side surface of the photoelectric conversion layer is covered by the rear surface electrode. Since leakage current increases when the photoelectric conversion layer comes close to the rear surface electrode in the power generation area, the other side surface is formed with a considerable distance from the power generation area. Therefore, it is difficult to put light, transmitting from the other side surface toward the rear surface side, back to the power generation area, resulting in low light use efficiency.

An objective of the present invention is to improve light use efficiency of thin film solar cells, and to achieve thin film solar cell modules easily manufacturable.

### Means for Solving the Problem

A thin film solar cell module of the present invention is a thin film solar cell module arranged with a plurality of cells in which a transparent electrode, a photoelectric conversion layer, and a rear surface electrode are stacked in this order on a translucent insulation substrate, and the thin film solar cell module includes, between adjacent cells:

a transparent electrode separation trench for separating the transparent electrode between the cells;

a rear surface electrode separation trench for separating the rear surface electrode between the cells; and

a cell connection apertural area, located between the transparent electrode separation trench and the rear surface electrode separation trench, for electrically connecting the rear surface electrode of one of the cells and the transparent electrode of another of the cells; wherein

photoelectric conversion layer separation trenches in which the photoelectric conversion layer is removed are provided between the cell connection apertural area and the transparent electrode separation trench and in an area from the cell connection apertural area through the rear surface electrode separation trench; and

white reflection material having an insulation property is formed at the inside of the photoelectric conversion layer separation trench.

A method of manufacturing a thin film solar cell module of the present invention is a method of manufacturing a thin film solar cell module arranged with a plurality of cells in which a transparent electrode, a photoelectric conversion layer, and a rear surface electrode are stacked in this order, and the method includes:

Process A for forming a transparent electrode on a translucent insulation substrate;

Process B for forming a transparent electrode separation trench to separate the transparent electrode between the cells;

Process C for forming a photoelectric conversion layer on the transparent electrode;

Process D for forming a cell connection apertural area in which the photoelectric conversion layer is removed and whose bottom portion reaches the transparent electrode;

Process E for forming a rear surface electrode on the photoelectric conversion layer;

Process F for electrically connecting the rear surface electrode of one of the cells and the transparent electrode of another of the cells at the inside of the cell connection apertural area;

Process G for forming a rear surface electrode separation trench to separate the rear surface electrode between the cells;

Process H for forming, in an area from the cell connection apertural area through the transparent electrode separation trench, a first photoelectric conversion layer separation trench in which the photoelectric conversion layer is removed;

Process I for forming white reflection material by coating paint containing white pigment in the first photoelectric conversion layer separation trench formed in Process H;

Process J for forming, in an area from the cell connection apertural area through the rear surface electrode separation trench, a second photoelectric conversion layer separation trench in which the photoelectric conversion layer is removed; and

Process K for forming white reflection material by coating paint containing white pigment in the second photoelectric conversion layer separation trench formed in Process J.

### ADVANTAGEOUS EFFECTS OF THE INVENTION

According to the thin film solar cell module of the present invention, since the white reflection material is formed on the photoelectric conversion layer on both sides of the cell connection apertural area for electrically connecting the adjacent cells, light passing through a non-power generation area toward a rear surface side can be efficiently guided into the photoelectric conversion layer, thereby improving light use efficiency of the thin film solar cell. Also, according to the manufacturing method of the thin film solar cell module of the present invention, because the white reflection material is formed by coating the paint containing the white pigment, it is easy to manufacture.

### BRIEF DESCRIPTION OF DRAWINGS

FIG. 1 is a plan view showing a configuration example of a thin film solar cell module according to Embodiment 1 of the present invention.

FIG. 2 is a partial cross sectional view of the thin film solar cell module according to Embodiment 1 of the present invention.

FIG. 3 is a partial cross sectional view illustrating a manufacturing method of the thin film solar cell module according to Embodiment 1 of the present invention.

FIG. 4 is a partial cross sectional view illustrating the manufacturing method of the thin film solar cell module according to Embodiment 1 of the present invention.

FIG. 5 is a partial cross sectional view of a thin film solar cell module according to Embodiment 2 of the present invention.

FIG. 6 is a partial perspective view of the thin film solar cell module according to Embodiment 2 of the present invention.

FIG. 7 is a partial cross sectional view illustrating a manufacturing method of the thin film solar cell module according to Embodiment 2 of the present invention.

FIG. 8 is a partial cross sectional view illustrating the manufacturing method of the thin film solar cell module according to Embodiment 2 of the present invention.

FIG. 9 is a partial perspective view of a thin film solar cell module according to Embodiment 3 of the present invention.

FIG. 10 is a partial cross sectional view illustrating a manufacturing method of the thin film solar cell module according to Embodiment 3 of the present invention.

FIG. 11 is a partial cross sectional view illustrating the manufacturing method of the thin film solar cell module according to Embodiment 3 of the present invention.

### MODE FOR CARRYING OUT THE INVENTION

Hereinafter, embodiments of thin film solar cell modules and manufacturing methods thereof according to the present invention are described with reference to the drawings. Note that the present invention is not limited to the description below, and is arbitrarily changeable without departing from the gist of the present invention. Also, for easy understanding, a scale of each element may differ from the actual one in the following drawings. The same applies to each scale of the drawings. In addition, the same elements are represented by the same reference numerals in the embodiments, and when an element is already described in an embodiment, its precise description will be skipped in another embodiment.

### Embodiment 1

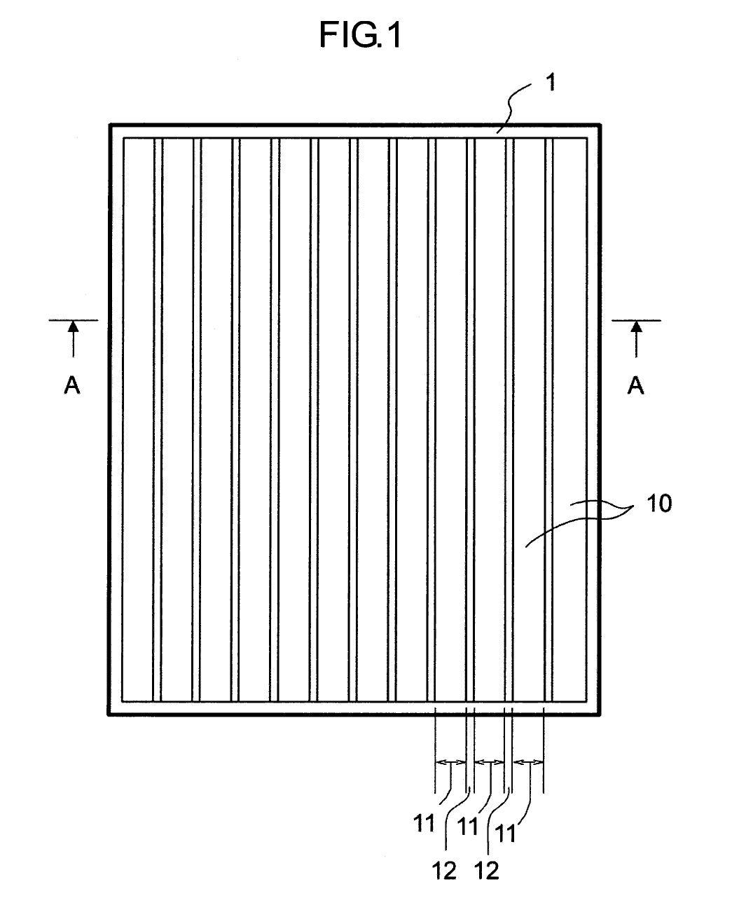

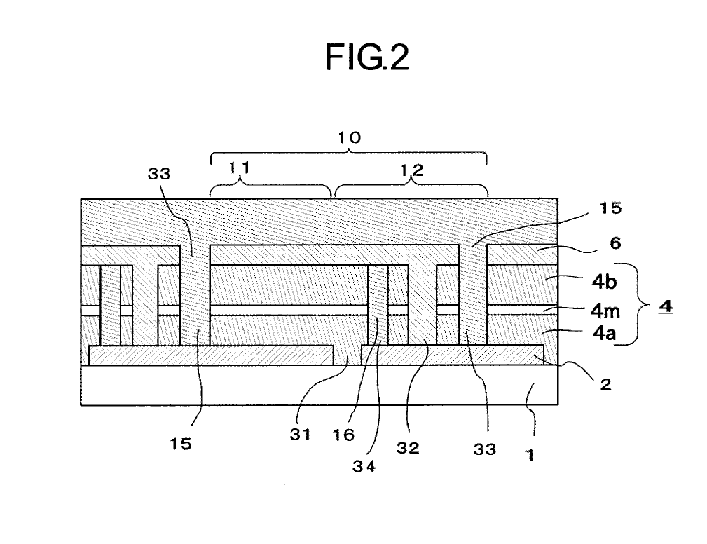

FIG. 1 is a plan view showing a configuration example of a thin film solar cell module according to Embodiment 1. FIG. 2 is a partial cross sectional view of the thin film solar cell module according to Embodiment 1, and shows part of a cross-section A-A in FIG. 1. As shown in FIG. 1, in the module according to Embodiment 1, a plurality of unit solar cells 10 having a slender rectangular shape are arranged in the direction along the short side of their rectangles on a translucent insulation substrate 1. Each of the unit solar cells 10 (unit solar cell is simply abbreviated to “cell” hereinafter) has a power generation area 11 for mainly generating power and a connection area 12 for mainly connecting the cells electrically, and they are arranged alternately with a predetermined gap in their short side direction. Each of the cells 10 is electrically connected in series in the connection area 12 located between the adjacent cells 10. As shown in FIG. 2, the cell 10 has a configuration in which a transparent electrode 2, a photoelectric conversion layer 4, and a rear surface electrode 6 are stacked in this order on the translucent insulation substrate 1. Incident light having entered the translucent insulation substrate 1 from its front surface, which is opposite to the stacked layers, enters the photoelectric conversion layer 4 via the transparent electrode 2 to be photoelectrically converted. Electric power generated at the photoelectric conversion layer 4 is outputted from the transparent electrode 2 and the rear surface electrode 6. The photoelectric conversion layer 4 in FIG. 2 has a tandem type structure in which a first photoelectric conversion layer 4a and a second photoelectric conversion layer 4b that has different photoelectric conversion wavelength dependence from the first photoelectric conversion layer 4a are stacked. Between the first photoelectric conversion layer 4a and the second photoelectric conversion layer 4b, a translucent and conductive middle layer 4m is provided. Note that the photoelectric conversion layer 4 may not be a tandem type but have a single layer structure, and also may have a multilayer structure of more than two.

The connection area 12 is a portion shared by the adjacent cells. In the connection area 12, the transparent electrode 2, the photoelectric conversion layer 4, and the rear surface electrode 6 are separated by a continuous trench formed between the adjacent cells in the long side direction of the rectangular cell. A transparent electrode separation trench 31 is formed in the transparent electrode 2 to separate it between the cells, and in the photoelectric conversion layer 4 stacked on it, a cell connection trench 32 and a rear surface electrode separation trench 33 are formed. While the cell connection trench 32 is provided as a continuous apertural area, it may be discontinuous apertural areas. The rear surface electrode separation trench 33 is a continuous trench for separating the photoelectric conversion layer 4 between the cells, along with the rear surface electrode 6 between the cells. Note that the positions of the photoelectric conversion layer 4 separation trench and the rear surface electrode 6 separation trench between the cells may be out of alignment with each other.

The rear surface electrode 6 of one of adjacent cells is electrically connected in series to the transparent electrode 2 of the other cell via the cell connection trench 32. The cell connection trench 32 is formed at an area sandwiched by the transparent electrode separation trench 31 and the rear surface electrode separation trench 33. In Embodiment 1, a structure is employed in which the rear surface electrode 6 is formed in the cell connection trench 32 and the rear surface electrode 6 is directly contact with the transparent electrode 2 located at the bottom portion of the cell connection trench 32. Note that the series-connection may be made via another electrical connection material in place of the rear surface electrode 6.

The connection area 12 from the transparent electrode separation trench 31 through the rear surface electrode separation trench 33 is the connection area 12 having a function of mainly connecting the cells and being a non-power generation area which hardly contributes to photoelectric conversion. In order to improve photoelectric conversion efficiency by making the non-power generation area smaller, a gap between these trenches is set as narrow as possible compared to the power generation area 11 in which no trench is formed. For example, when viewed from the perpendicular direction with respect to the main surface of the translucent insulation substrate 1, a structure is employed in which the transparent electrode separation trench 31 and the rear surface electrode separation trench 33 are closely arranged in parallel and the cell connection trench 32 is located at a narrow gap between them.

The transparent electrode 2 of the other cell 10 is extended from the lower portion of the photoelectric conversion layer 4 through, at least, the bottom portion of the connection trench 32. Therefore, the rear surface electrode separation trench 33 for separating the photoelectric conversion layer 4 between the cells is formed so as not to completely separate the transparent electrode 2, even when the trench is formed so that the bottom portion thereof reaches the transparent electrode 2. When the substrate is viewed from the perpendicular direction with respect to its main surface, the connection area 12 is configured to separate the conductive layer constituting the cell and to electrically connect the rear surface electrode 6 of a cell and the transparent electrode 2 of another cell at their overlapping portion in which both electrodes are extended with each other from the power generation areas 11.

In Embodiment 1,a first photoelectric conversion layer separation trench 34 (abbreviated to “first separation trench” hereinafter) in which the photoelectric conversion layer 4 is removed is located at one cell side of the cell connection trench 32 as the apertural area used for electrical connection, and the rear surface electrode separation trench 33 is located at the other cell side as a second photoelectric conversion layer separation trench (abbreviated to “second separation trench” hereinafter) in which the photoelectric conversion layer is removed. Thus, the first separation trench 34 in which the photoelectric conversion layer 4 is removed is located between the cell connection trench 32 and the transparent electrode separation trench 31, and the rear surface electrode separation trench 33 as the second separation trench in which the photoelectric conversion layer is removed is located in an area from the cell connection trench 32 through the rear surface electrode separation trench 33. Inside of these two photoelectric conversion layer separation trenches, first white reflection material 16 and second white reflection material 15 having an electrical insulation property are formed.

The first separation trench 34 is located between the transparent electrode separation trench 31 and the cell connection trench 32. The trench 34 is formed substantially parallel to the transparent electrode separation trench 31 along the longitudinal direction of the cell 10. The trench 34, in which the photoelectric conversion layer 4 is ablated by a laser scribing method or the like, separates the photoelectric conversion layer 4 between the cells, and has the transparent electrode 2 as its bottom portion. The rear surface electrode 6 of one of adjacent cells 10 crosses over the first white reflection material 16 of the first separation trench 34 to be connected to the transparent electrode 2 of the other cell 10 in the cell connection trench 32.

The rear surface electrode separation trench 33 as the second separation trench is also formed along the longitudinal direction of the cell 10 by ablating the photoelectric conversion layer 4 with a laser scribing method or the like, and has the transparent electrode 2 as its bottom portion. While the figure shows a case in which the white reflection material 15 is formed to cover the entire rear surface of the cell 10 including the inside of the rear surface electrode separation trench 33 and the top portion of the rear surface electrode 6, it may be formed locally, for reducing material usage, such as only in the rear surface electrode separation trench 33 or only in the trench and its neighboring portion with scarcely covering the top portion of the rear surface electrode 6. Although it is preferable to use the same material for the first white reflection material 16 formed in the first separation trench 34 and the second white reflection material 15 formed in the rear surface electrode separation trench 33, materials having different reflectance characteristics etc. may be used.

As the first and second white reflection materials 16 and 15, a mixture of white insulation particles and transparent insulation resin may be used. In this case, it may be helpful to use white insulation particles having a diameter smaller than the depth of the rear surface electrode separation trench 33. As material for the white insulation particles, there can be used powder of titanium oxide, zinc oxide, barium sulfate, calcium carbonate, magnesium oxide, aluminum oxide, and the like which are known as white pigment. It may be helpful to use pigment presenting white color having high reflectance specifically in a visible light range. The diameter of these particles is to be 0.1-2 μm. It is more preferable to select adequate powder from this range having a diameter smaller than the depth of the rear surface electrode separation trench 33, and it may be helpful to set the average particle diameter to be 0.2-0.5 μm when the depth of the rear surface electrode separation trench 33 is from 1 to several μm. Such a microscopic particle diameter can be measured by a laser diffraction/scattering particle diameter distribution measurement device. As the transparent insulation resin, acrylic resin, alkyd resin, phenol resin, vinyl resin, and fluororesin can be used. This resin component acts as bonding material to bind the white insulation particles with each other and to fix them on a base. As the white reflection materials 16 and 15, there can be used white paint, which is composed mostly of various types of white pigment, having high reflectance from the visible light range through the infrared light range. In order to have high reflectance in a wavelength range of 400-600 μm in which solar light energy on the land surface is especially high, it is preferable that only the white pigment is employed and colored pigment other than the white one is not included. As the white pigment, the white reflection material 15 can be formed by using, for example, 10-40% by mass of white pigment particle such as titanium oxide, 10-30% by mass of transparent resin, 30-80% by mass of organic solvent, and other additive agents so that total % by mass becomes 100. Per 100 parts by mass of resin configuring a white coating film, 20-200 parts by mass of white pigment particle may be contained. While there is a case in which the width of the rear surface electrode separation trench 33 where the white reflection material 15 is formed and of other trenches where the white reflection material is formed as described below, is as small as 10 μm, even in such a narrow trench case, it may be helpful to use material, whose pigment mass ratio is increased, for the reflection material so that the reflectance, when coated as a 10 μm thickness film, becomes no less than 60%, preferably no less than 70%, in a wavelength range of 400-600 μm.

In the first and second white reflection materials 16 and 15, white pigment particles are dispersed within the transparent resin. A refractive index of the resin differs from that of the pigment particles, and since numerous microscopic interfaces are present in random directions to become reflection surfaces, light having entered the white reflection material is diffusely reflected. Thus, the first and second white reflection materials 16 and 15 are material of diffusely reflecting light.

The transparent electrode 2 is configured with a transparent conductive oxide film such as ZnO, ITO (Indium Tin Oxide), and SnO₂, or a film in which metallic material such as aluminum or gallium is added to ZnO.

The photoelectric conversion layer 4, having a PN junction or PIN junction, is configured with one or stacked multilayer thin film semiconductor layers which generate power with incident light entering the light-incident face (lower side face in FIG. 2) of the thin film solar cell. As the thin film semiconductor layer, for example, there can be used hydrogenated amorphous silicon, microcrystal silicon, amorphous silicon germanium, microcrystal silicon germanium, amorphous silicon carbide, microcrystal silicon carbide, and the like. When the photoelectric conversion layer 4 is configured by stacking a plurality of thin film semiconductor layers, a transparent conductive film such as ITO and ZnO, or a silicon compound film such as silicon oxide and silicon nitride whose conductivity is improved by doping with impurities can be inserted between the thin film semiconductor layers as the middle layer 4m.

The rear surface electrode 6 is preferable to have a structure in which a transparent conductive film and a metal film are stacked in this order from the semiconductor layer contacting side. By inserting the transparent conductive film between the semiconductor layer and the metal film, a phenomenon can be inhibited in which cell characteristics of the solar cell are degraded with diffusion of the metal film component into the semiconductor layer. Inserting the transparent conductive film also makes it possible to get a function of enhancing an optical confinement effect which is effective for improving solar cell efficiency. As described above, SnO₂, ITO, ZnO and the like can be used as the transparent conductive film material. The metal film material is preferably configured with material which has high conductivity and high optical reflectance. For example, there can be used metal film material such as silver, gold, aluminum, chrome, titanium, and nickel.

As described above, the thin film solar cell module according to Embodiment 1 has, at both sides of the cell connection trench 32 as the cell connection apertural area, the photoelectric conversion layer separation trench 34 and the rear surface electrode separation trench 33 in which the photoelectric conversion layer is removed, and the first and second white reflection materials 16 and 15 having an insulation property are formed at the inside of these trenches. The second white reflection material 15 contacts the side surface of the photoelectric conversion layer 4 at one end portion of the power generation area 11, and moreover, the first separation trench 34 is provided at a nearer portion than the cell connection trench 32 to the power generation area 11, and the first white reflection material 16 contacts the side surface of the photoelectric conversion layer 4 at the inside of the trench. Therefore, incident light to the power generation area 11 can be utilized effectively.

Both bottom portions of the photoelectric conversion layer separation trench 34 and the rear surface electrode separation trench 33 are the transparent electrode 2, and the first and second white reflection materials 16 and 15 are formed on the transparent electrode 2 at the bottom portion. Since the white reflection materials 16 and 15 are diffuse reflective material, part of light having directly entered the connection area 12 is diffusely reflected at the bottom portions of the white reflection materials 16 and 15 to be reflected to the front surface of the translucent insulation substrate 1 at a shallow angle. The light can be effectively utilized since it is reflected again at the front surface of the translucent insulation substrate 1 and enters the photoelectric conversion layer 4. In addition, since both of the white reflection materials 16 and 15 have the same height from the substrate at their base as that of the photoelectric conversion layer 4 and have no protrusion beyond the photoelectric conversion layer 4 toward the beam incident side, the light obliquely entering the photoelectric conversion layer 4 in the power generation area 11 is not interrupted.

Because the cell connection trench 32 and the photoelectric conversion layer 4 are electrically separated at both sides by the first separation trench 34 and the rear surface electrode separation trench 33 as the second separation trench, leakage in a transverse direction is prevented. Since keeping a considerable distance between the cell connection trench 32 and the power generation area 11 for preventing the leakage is not needed, it is possible to locate the transparent electrode separation trench 31 closer to the cell connection trench 32, thereby narrowing the width of the connection area 12, which is the non-power generation area.

As the side surface of the photoelectric conversion layer 4 is covered by insulation material, generation of leakage current caused by conductive foreign substances entering the trench is prevented. In Embodiment 1, since the second white reflection material 15 covers not only the trenches of the photoelectric conversion layer 4 but also the entire top surface of the rear surface electrode 6, there is obtained an effect of mechanically and chemically protecting the rear surface electrode 6.

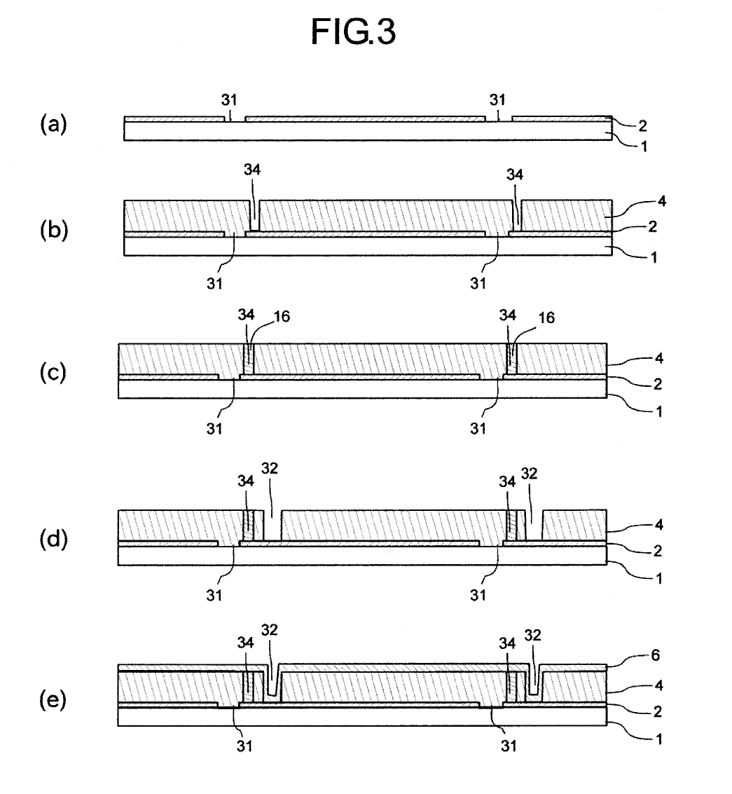

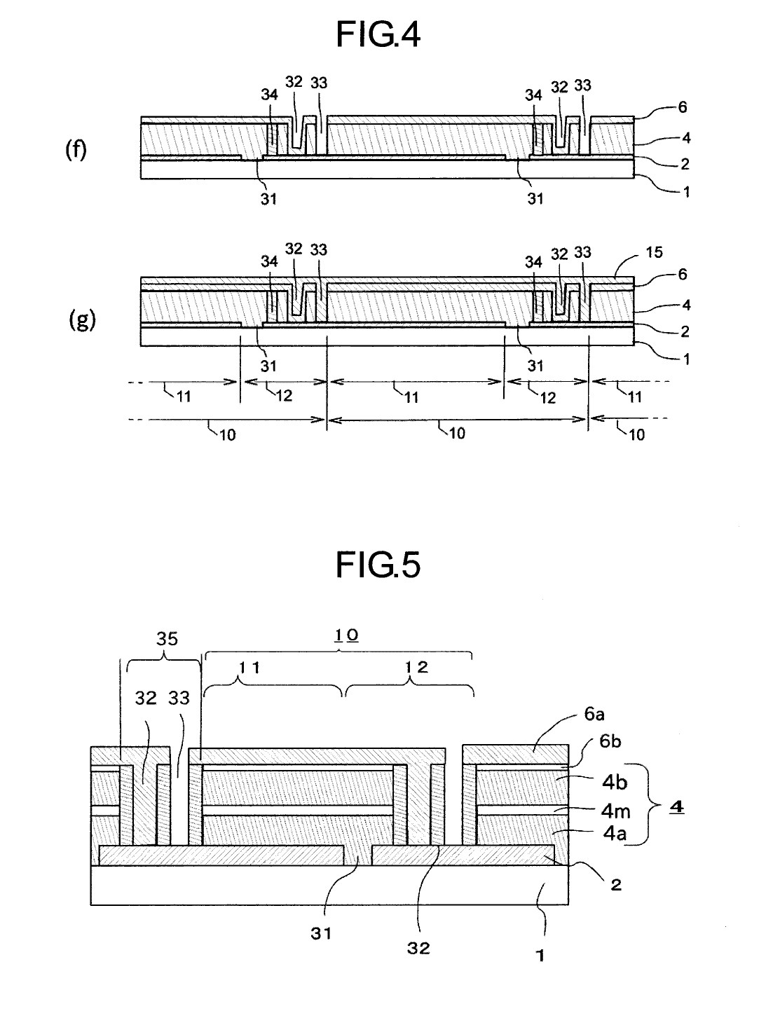

Hereinafter, a manufacturing method of the thin film solar cell module according to Embodiment 1 is described. FIGS. 3 and 4 are partial cross sectional views illustrating the manufacturing method of the thin film solar cell module according to Embodiment 1. First, as shown in FIG. 3(a), the transparent electrode 2 separated by the transparent electrode separation trench 31 corresponding to each cell 10 is formed on the translucent insulation substrate 1 consisting of, for example, a white plate glass. Thus, there are executed Process A for forming the transparent electrode and Process B for forming the transparent electrode separation trench to separate the transparent electrode between the cells. There are several methods such as the one executing Process A and Process B concurrently in which the transparent electrode 2 is deposited on the substrate by using a mask so as not to be deposited on the portion corresponding to the transparent electrode separation trench 31, and the one in which, after executing Process A for forming the transparent electrode 2 on the entire surface of the translucent insulation substrate 1, Process B is executed to form the transparent electrode separation trench 31 by processing the transparent electrode 2. For the transparent electrode 2, a ZnO film doped with, for example, aluminum can be formed by a sputtering method, etc. As a method of processing the transparent electrode 2 to form the transparent electrode separation trench 31, there are a laser scribing method and a wet etching method using a resist mask. When the translucent insulation substrate 1 has a rectangular shape, it may be helpful to form the transparent electrode separation trenches 31 being arranged in parallel, having a predetermined gap, with respect to one side of the translucent insulation substrate 1.

Next, as shown in FIG. 3(b), Process C is executed to form the photoelectric conversion layer 4 consisting of semiconductor material on the transparent electrode 2. And then, Process H is executed to form the first separation trench 34 by partly removing the photoelectric conversion layer 4. The first separation trench 34 is processed so that the transparent electrode 2 remains at the bottom portion thereof. The first separation trench 34 is formed at a neighboring position slightly shifted from the transparent electrode separation trench 31. The position is located within an area between the transparent electrode separation trench 31 and the cell connection trench 32 which is formed in a later process.

In Process C, the photoelectric conversion layer 4 is deposited by a CVD method. When the photoelectric conversion layer 4 is a multi-junction type, layers are deposited in the following order, for example: a thin film semiconductor layer of hydrogenated amorphous silicon thin film as the first photoelectric conversion layer 4a; next, a silicon oxide film doped with impurities as the middle layer 4m; and thereon, a thin film semiconductor layer of microcrystal silicon thin film as the second photoelectric conversion layer 4b. Note that the photoelectric conversion layer 4 may be a single layer, or have a multilayer junction structure. Layers of other material such as a compound, semiconductor may be used as the semiconductor material.

The first separation trench 34 in Process H can be formed by using a laser scribing method. When the photoelectric conversion layer 4 is composed mostly of silicon, a trench having the exposed transparent electrode 2 as its bottom portion can be comparatively easily formed by using a second harmonics of Nd:YAG laser as a light source. The trench is formed to be extended along the longitudinal direction of the cell 10, so that the photoelectric conversion layer 4 is separated by the trench corresponding to each cell 10.

After that, as shown in FIG. 3(c), Process I is executed to form the first white reflection material 16 by coating the inside of the first separation trench 34 with the white paint which contains white pigment particles having an electrical insulation property. The first white reflection material 16 is formed by coating the rear surface electrode separation trench 33 with the white paint which contains titanium oxide micro particles as the white pigment. The productivity is better when using, as the paint, a white ink consisting of 10-40% by mass of titanium dioxide particles having an average particle diameter of, for example, 0.2-0.3 μm, 10-30% by mass of synthetic resin, and 30-80% by mass of solvent having a highly-volatile property such as hydrocarbon system, ester, alcohol system, ketone system, and ether system.

In process I, coating with the white paint is executed locally, that is only the inside of the first separation trench 34, or the limited neighboring area including the trench is coated. Such a local coating of the trench with the white paint can be executed by a method of using dispenser, inkjet, or screen printing. Although it is illustrated in the figure that the separation trench 34 is completely filled with the first white reflection material 16, the trench is not necessarily completely filled as long as the side surface and the bottom surface of the photoelectric conversion layer 4 in the separation trench 34 are coated. At the coating, the first white reflection material 16 may run off the edge of the separation trench 34 to some neighboring portion on the rear surface electrode 6. The volatile component such as the solvent contained in the white paint is removed by the heat treatment, etc. after the coating.

And then, as shown in FIG. 3(d), Process D is executed to form the cell connection trench 32 as the cell connection apertural area by removing the photoelectric conversion layer 4 so that the bottom portion of the apertural area reaches the underlying transparent electrode 2. The cell connection trench 32 is formed at an area sandwiched by the transparent electrode separation trench 31 and the rear surface electrode separation trench 33 which will be formed later, namely formed neighboring the white reflection material 16 and opposite to the transparent electrode separation trench 31. The cell connection trench 32 can be formed by also using a laser scribing method similarly to the first separation trench 34.

Next, as shown in FIG. 3(e), Process E is executed to form the rear surface electrode 6 on the photoelectric conversion layer 4. The rear surface electrode 6 also covers the inside surface of the cell connection trench 32, and contacts the transparent electrode 2 located at the bottom portion of the trench. In this way, Process F is executed concurrently with Process E, to electrically connect the rear surface electrode 6 of one of adjacent cells 10 to the transparent electrode 2 of the other cell at the inside of the cell connection trench 32. Note that Process F is not necessarily executed concurrently with Process E, and may be executed as another process by using, for example, conductive paste, etc.

For the rear surface electrode 6 in Process E, it is preferable to form the rear surface electrode 6 having a structure in which the oxide transparent conductive film and the metal film are stacked in this order from the semiconductor layer contacting side. A thin film is formed by using, for example, zinc oxide doped with aluminum as the oxide transparent conductive film material. While a sputtering method, for example, can be used as a film formation method, there is no particular limitation and any other method such as a CVD method and a coating method may be used. After that, the rear surface electrode 6 is formed by depositing a metal thin film of, for example, silver which has high optical reflectance as a metal film. While a sputtering method, for example, can be used as a film formation method, there is no particular limitation and any other method such as an electron beam type vapor deposition method and a coating method may be used. The oxide transparent conductive film can prevent degradation caused by mutual diffusion when the semiconductor layer directly contacts the metal layer. Such an effect is prominent when the semiconductor layer mostly composed of silicon is combined with the metal film mostly composed of silver. By setting a thickness of the oxide transparent conductive film equal to that of an optical interference film, the reflectance can be increased when the light passing through the photoelectric conversion layer 4 is reflected toward the photoelectric conversion layer 4 again.

And then, as shown in FIG. 4(f), Process G is executed to form the rear surface electrode separation trench 33 for separating the rear surface electrode 6 between the cells. The rear surface electrode separation trench 33 is formed at a position adjacent to the cell connection trench 32 and opposite to the transparent electrode separation trench 31. The rear surface electrode separation trench 33 separates not only the rear surface electrode 6 between the cells, but also the photoelectric conversion layer 4 on the transparent electrode 2. Since the rear surface electrode separation trench 33 serves also as the second separation trench, Process J is executed concurrently with Process G, to form the second separation trench in which the photoelectric conversion layer is removed between the cell connection trench 32 and the rear surface electrode separation trench 33. The rear surface electrode separation trench 33, extended along the longitudinal direction of the cell 10, is provided as a trench reaching the transparent electrode 2 from the transparent electrode 2 surface. As a method for forming such a trench, an etching method using a resist mask and a laser scribing method can be used. While Process G and Process J may be executed independently, Process G and Process J can be executed concurrently by employing a method in which the rear surface electrode 6 together with the photoelectric conversion layer 4 are ablated by, for example, a laser scribing method of irradiating a laser beam from the front surface side of the translucent insulation substrate 1, which makes the process easier.

Next, Process K is executed to form the second white reflection material 15 in the rear surface electrode separation trench 33, which is the second separation trench formed in Process J as shown in FIG. 3(e). The second white reflection material 15 is formed by coating the paint which contains the white pigment, similarly to the first white reflection material 16. The coated film is formed by evaporating the solvent by baking after the coating.

Material having a high ratio of white pigment component is preferable as the paint, in which a mass ratio of the white pigment component with respect to the resin component in the coated film is, for example, no less than 40%. When the ratio of the white pigment component is increased, even a thin film, for example, around 1-10 μm can become the white reflection materials 16 and 15 which have an excellent reflectance property.

While various kinds of material can be used as the white pigment, material having a high optical refractive index is preferable. Because diffuse reflection of light arises when a surface of a micro particle and its surroundings have different refractive indexes, titanium oxide is excellent material, which has a larger difference of the refractive index compared to the transparent resin in the coated film. Furthermore, while an anatase type titanium oxide particle has an excellent reflection property, it has a function of resolving resin under the ultraviolet light, therefore using a rutile type particle is preferable for a long-term usage.

As a coating method for such a paint, there can be employed a method of coating the entire top surface of the cell 10 by spraying or with a roller, or a method of local coating in which the inside of the rear surface electrode separation trench 33 is filled with the paint by using dispenser, inkjet, or screen printing. While it is preferable to cover the entire top surface of the cell 10 uniformly from a standpoint of protecting the cell 10, it is preferable to coat locally from a standpoint of decreasing the material usage. Acrylic paint may be baking finished at a temperature of 100-150° C. after the coating, which brings a coating film having excellent durability and less degrading over a long period of time. By executing a process of heating at 100-150° C., a process of decompression treatment, or the like after coating the paint, the solvent component is removed at a faster speed, thereby being able to accelerate the manufacturing speed.

Through the above described processes, a thin film solar cell module is completed basically. After that, while not shown in the figures, through a further sealing process in which protection material such as a sealing sheet is adhered on the translucent insulation substrate 1 with adhesive material or the like, the thin film solar cell module is made usable outdoors over a long period of time.

As described above, the manufacturing method of the thin film solar cell module according to Embodiment 1 includes, on the translucent insulation substrate 1, Process A for forming the transparent electrode 2 on the translucent insulation substrate 1, Process B for forming the transparent electrode separation trench 31 to separate the transparent electrode 2 between the cells, Process C for forming the photoelectric conversion layer 4 on the transparent electrode 2, Process D for forming the cell connection apertural area (cell apertural trench 32) by removing the photoelectric conversion layer 4 so that the bottom portion of the trench reaches the transparent electrode 2, Process E for forming the rear surface electrode 6 on the photoelectric conversion layer 4, Process F for electrically connecting the rear surface electrode 6 of a cell 10 and the transparent electrode 2 of another cell 10 at the inside of the cell connection apertural area (cell apertural trench 32), and Process G for forming the rear surface electrode separation trench 33 to separate the rear surface electrode 6 between the cells. According to Embodiment 1, further included are Process H for forming the first separation trench 34, in which the photoelectric conversion layer 4 is removed, between the cell connection apertural area (cell apertural trench 32) and the transparent electrode separation trench 31, Process I for forming the first white reflection material 16 by coating the first separation trench formed in Process H with the white paint containing the white pigment, Process J for forming the second separation trench (rear surface electrode separation trench 33), in which the photoelectric conversion layer 4 is removed, in an area from the cell connection apertural area (cell apertural trench 32) through the rear surface electrode separation trench 33, and Process K for forming the second white reflection material 15 in the second separation trench (rear surface electrode separation trench 33) formed in Process J by coating the paint containing the white pigment. In this way, trenches for separating the photoelectric conversion layer 4 are provided on both sides of the connection apertural area in Process H and Process J. These separation trenches serve as both ends of the photoelectric conversion layer 4 of the power generation area 11, and the first and second white reflection materials 16 and 15 are provided at these ends in Process I and Process K. Note that, as far as no inconvenience arises, the order of the processes may be changed, a plurality of processes may be executed in one process, and one process may be divided and executed in a plurality of processes. Since the white light-reflecting material is formed by coating the paint which contains white particles having an electrical insulation property in Process I and Process K, a thin film solar cell with high efficiency can be easily manufactured in which the light to pass through the cell connection structure portion toward the backside thereof can be guided into the photoelectric conversion layer with high reflectance. Also, since higher optical reflectance can be obtained with thinner coating film compared to a sealing sheet having an optical reflectance or adhesive material containing a reflection component, the material usage can be reduced. When a sealing sheet, etc. is adhered to the rear surface side, an optical reflection property or transmission property is not necessary for the adhesive material. Therefore, inexpensive adhesive material can be selected, which is advantageous in cost reduction.

### Embodiment 2

FIG. 5 is a partial cross sectional view of a thin film solar cell module according to Embodiment 2 and is the cross sectional view at a position corresponding to FIG. 2 in Embodiment 1. In the thin film solar cell module according to Embodiment 2, while it is the same with Embodiment 1 that the white reflection material is provided on the side surfaces of the photoelectric conversion layer 4 of the cells on both sides of the cell connection trench 32, it is different in Embodiment 2 that the cell connection trench 32 is formed at the inside of the white reflection material. A separation trench 35 between the cells is provided in the photoelectric conversion layer 4, and the cell connection trench 32 and the rear surface electrode separation trench 33 are formed in the white reflection material formed at the inside of the separation trench 35.

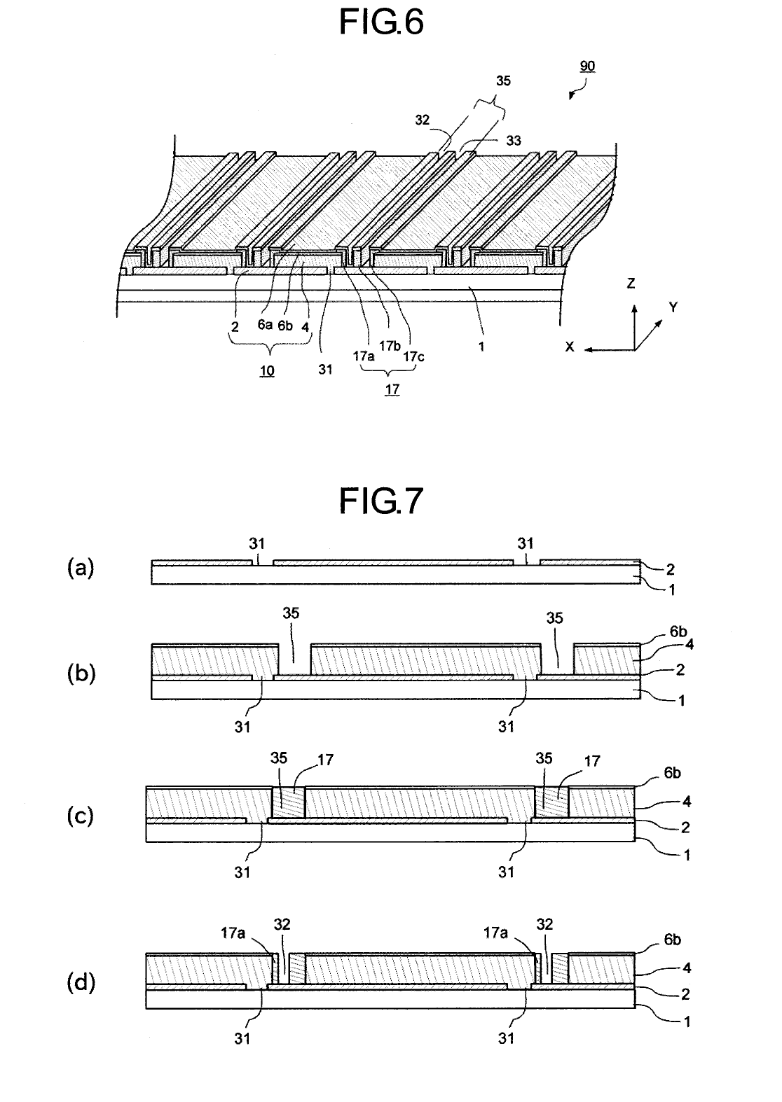

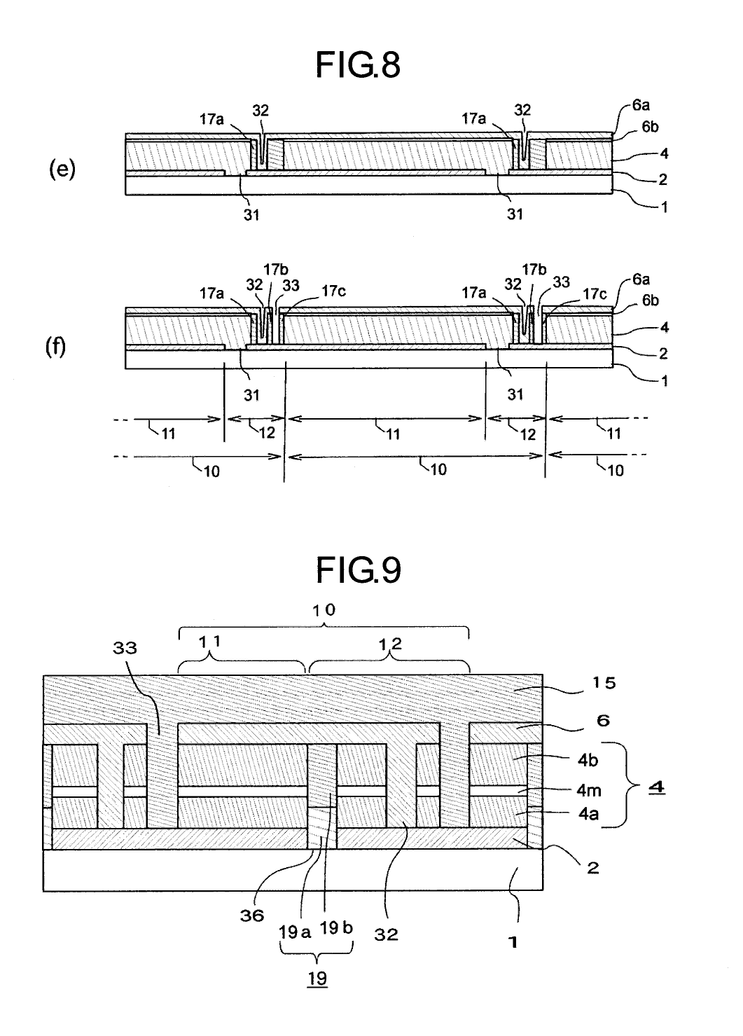

FIG. 6 is a partial perspective view of the thin film solar cell module according to Embodiment 2. Many rectangular cells 10 are arranged on the translucent insulation substrate 1 in the X-direction (short side direction of the rectangle) in the figure, and the separation trenches 35 of the photoelectric conversion layer 4 are extended between the cells 10 in the Y-direction (long side direction of the rectangle) perpendicular to the X-direction. This is the only trench formed to separate the photoelectric conversion layer 4 between the cells. White reflection material 17 is formed in the separation trench 35, and the cell connection trench 32 and the rear surface electrode separation trench 33 are provided in the white reflection material 17. The cell connection trench 32 and the rear surface electrode separation trench 33 are formed at positions a little distant from the side surfaces of the photoelectric conversion layer 4. Therefore, in the separation trench 35, a white reflection material portion 17a which contacts one side surface of the photoelectric conversion layer 4 and a white reflection material portion 17c which contacts the other side surface thereof are separately provided. When the cell connection trench 32 is formed as a continuous trench in the longitudinal direction of the cell 10, a white reflection material portion 17b is formed between the white reflection material portions 17a and 17c. The rear surface electrode 6 includes a first rear surface electrode 6a consisting of a metal film, etc. and a second rear surface electrode 6b consisting of a transparent conductive film, etc. The second rear surface electrode 6b is in contact with and sandwiched by the photoelectric conversion layer 4 and the first rear surface electrode 6a. While a case is shown in FIG. 8 in which some part of the white reflection material portions 17a and 17c are also formed on the second rear surface electrode 6b, it may be formed only in the trench as shown in FIG. 5. Also, the rear surface electrode 6 is not necessarily multi-layered, but may be a single layer.

Thus, in the thin film solar cell module according to Embodiment 2, after removing part of the photoelectric conversion layer 4 at the transparent electrode separation trench 31 side when viewed from the cell connection trench 32, the white reflection material portion 17a is inserted, and after removing part of the photoelectric conversion layer 4 at the rear surface electrode separation trench 33 side when viewed from the cell connection trench 32, the white reflection material portion 17c is inserted. That is, similar to Embodiment 1, the white reflection material 17 contacting the side surfaces of the photoelectric conversion layer 4 is formed on both sides of the cell 10 in its longitudinal direction. The white reflection material portion 17a corresponds to the first white reflection material 16 in Embodiment 1, and the white reflection material portion 17c is equivalent to the second white reflection material 15. Therefore, similar to Embodiment 1, photoelectric conversion efficiency is increased and an effect of preventing leakage current is obtained. Also, because the cell connection trench 32 as the cell connection apertural area and the rear surface electrode separation trench 33 for separating the cells are formed in the white reflection material 17 at the inside of the separation trench 35, only a single trench, i.e. the separation trench 35, is formed in the photoelectric conversion layer 4 between the cells 10, thereby obtaining an effect of narrowing the width of the connection area 12.

Next, a manufacturing method of the thin film solar cell module according to Embodiment 2 is described. FIGS. 7 and 8 are partial cross sectional views illustrating the manufacturing method of the thin film solar cell module according to Embodiment 2. First, as shown in FIG. 7(a), the transparent electrode 2 separated by the transparent electrode separation trench 31 is formed on the translucent insulation substrate 1, which is similar to Process A and Process B in Embodiment 1.

Next, similar to Process C in Embodiment 1, the photoelectric conversion layer 4 consisting of semiconductor material is formed on the transparent electrode 2. In addition, as shown in FIG. 7(b), after forming the second rear surface electrode 6b consisting of a transparent conductive film on the photoelectric conversion layer 4 by a sputtering method, etc., the separation trench 35 whose bottom portion reaches the transparent electrode 2 is formed in the photoelectric conversion layer 4 and the second rear surface electrode 6b. The separation trench 35 can be formed by a laser scribing method, similar to Process H in Embodiment 1. The separation trench 35 is a combined trench which serves as the cell connection apertural area formed in Process D in Embodiment 1, the first separation trench formed in Process H, and the second separation trench formed in Process J. As such a single trench is formed between the cells, removing the photoelectric conversion layer 4 in Process D, Process H, and Process J is concurrently executed by forming the separation trench 35.

After that, as shown in FIG. 7(c), the white reflection material 17 is formed by filling the separation trench 35 with the white paint which contains white insulation pigment particles. The white reflection material 17 has a combined function which serves as the first white reflection material 16 formed in Process I in Embodiment 1 and the second white reflection material 15 formed in Process K. By forming the white reflection material 17, forming the white reflection material in Process I and Process K is concurrently executed.

Local coating of the trench with the white paint can be executed by a method of using dispenser, inkjet, or screen printing. Although it is illustrated in the figure that the separation trench 35 is completely filled with the white reflection material 17, the trench is not necessarily completely filled as long as the side surface of the photoelectric conversion layer 4 and the bottom portion in the separation trench 34 are coated. At the coating, the white reflection material 17 may partially run off the edge of the separation trench 35 to the neighboring area as shown in FIG. 6.

And then, as shown in FIG. 7(d), Process D is executed to form the cell connection trench 32 in the white reflection material 17 in the separation trench 35. The cell connection trench 32 is formed in the white reflection material 17 with a slight distance from the side surface, which is the side closer to the transparent electrode separation trench 31, of the photoelectric conversion layer 4. The cell connection trench 32 is a trench which reaches the transparent electrode 2, in the white reflection material 17. As a method for forming the white reflection material 17 in the cell connection trench 32, a processing method using a resist mask or a laser scribing method can be used.

When using a laser scribing method, it is preferable to appropriately select components of the white reflection material 17 formed in Process I and Process K, and a laser beam wavelength to be used. A trench is easily formed in the white reflection material 17 containing polyimide resin when processed by a laser scribing of irradiating a pulsed laser beam having a wavelength of 400-450 nm from the front surface of the translucent insulation substrate 1. As such a laser beam, 447 nm laser beam which is a third harmonics of Nd:YVO4 laser having a fundamental harmonic of 1,342 nm, for example, is suitable. While the polyimide resin is transparent within a visible light wavelength range, its absorption property suddenly increases in many cases when a light wavelength becomes less than 450 nm. When irradiating a high energy laser beam having a wavelength of no more than 450 nm on the polyimide resin, the resin is dissolved, loses its adhesive strength to the base, and is removed with the pigment particles contained thereto by the ablation. While such a processing is possible by irradiating a pulsed laser beam having a wavelength of 355 nm such as a third harmonics of Nd:YAG, since absorption in the transparent electrode 2 increases when a wavelength is shorter than 400 nm, using such a laser beam becomes difficult when the transparent electrode 2 is comparatively thick. Therefore, a better way is to use the white reflection material 17 containing resin material having a comparatively large absorption property at a wavelength of no less than 400 nm, and to execute a processing by a laser beam having a wavelength which is absorbed by the resin material. Also, there may be employed a method of adding resin having high transmittance in a visible light range and a high absorption property in a near infrared range as a component of the white reflection material 17, and executing laser processing using a near infrared laser beam corresponding to the absorption wavelength. As the resin having a high absorption property in the near infrared range, aromatic system resin, for example, can be used.

Next, similar to Process E and Process F in Embodiment 1, the inner surface of the cell connection trench 32 and the top portion of the second rear surface electrode 6b are covered by the first rear surface electrode 6a consisting of a metal film by using a sputtering method, etc., as shown in FIG. 8(e). In addition, as shown in FIG. 8(f), Process G is executed to form the rear surface electrode separation trench 33 in the white reflection material 17 for separating the first rear surface electrode 6a between the cells. The rear surface electrode separation trench 33 is formed in the white reflection material 17 having a slight distance to the side surface, which is the side farther from the transparent electrode separation trench 31, of the photoelectric conversion layer 4. The rear surface electrode separation trench 33 can be formed by using a laser scribing method as described in the explanation of Process D, by removing both the white reflection material 17 and the first rear surface electrode 6a on the transparent electrode 2, which is remained as the bottom portion thereof. While the thin film solar cell module according to Embodiment 2 is completed as described above, a further process may be executed to fill the inside of the rear surface electrode separation trench 33 with the white reflection material.

As described above, the manufacturing method of the thin film solar cell module according to Embodiment 2 includes a process of executing Process H and Process J concurrently, after forming the photoelectric conversion layer 4 on the transparent electrode 2 in Process A, Process B, and Process C, for forming the single separation trench 35, having the exposed transparent electrode 2 as its bottom portion, in the photoelectric conversion layer 4 between the cells; a process of executing Process I and Process K concurrently for forming the white reflection material 17 containing the white insulation material on the bottom portion of the separation trench 35 and the side surface of the photoelectric conversion layer 4 in the trench; Process D for forming the cell connection trench 32 in the white reflection material 17; Process E for forming the rear surface electrode 2 after Process D; Process F for electrically connecting the first rear surface electrode 6a of one of cells which are contiguous via the cell connection trench 32 and the transparent electrode 2 of the other cell; and Process G for forming the rear surface electrode separation trench 33 to separate the first rear surface electrode 6a between the cells by removing a portion of the white reflection material 17 in the separation trench 35 and the rear surface electrode 6 on the portion of the white reflection material 17.

In this way, because only a single trench, the separation trench 35, is enough for the trench in the photoelectric conversion layer 4 formed between the adjacent cells, it is easy to manufacture. Since a process for forming the white reflection material 17 on both sides of the cells 10 in their longitudinal direction is achieved in a single coating process, it is easily manufactured. By processing with the irradiation of a laser beam which is absorbed by the resin of the white reflection material 17 when forming the cell connection trench 32 as the apertural area and the rear surface electrode separation trench 33 in the separation trench 35, dissolving is possible with lower energy compared to inorganic material processing, therefore a processing can be executed with a laser beam having smaller energy density and also with higher speed. Because the second rear surface electrode 6b consisting of a transparent conductive film is formed on the photoelectric conversion layer 4 before forming the separation trench 35, contamination and degradation of the photoelectric conversion layer 4 can be prevented.

### Embodiment 3

FIG. 9 is a partial cross sectional view of a thin film solar cell module according to Embodiment 3 and is the cross sectional view at a position corresponding to FIG. 2 in Embodiment 1 and FIG. 5 in Embodiment 2. While the thin film solar cell module according to Embodiment 3 has a resemblance to that in Embodiment 1, it is different that there is provided first white reflection material 19 having white pigment whose concentration varies in perpendicular direction to the translucent insulation substrate 1.

In addition, in the thin film solar cell module according to Embodiment 3, a position of a separation trench in the photoelectric conversion layer 4 differs from that in Embodiment 1 and Embodiment 2, and a separation trench 36 concurrently separates the transparent electrode 2 and the photoelectric conversion layer 4. The first white reflection material 19 is formed in the separation trench 36. It has a structure in which the transparent electrode separation trench 31 and the first separation trench 34 in the structure in Embodiment 1 are combined straight as one separation trench 36. In the separation trench 36, the first white reflection material 19 is formed substantially in parallel along the longitudinal direction of the cell 10 in the transparent electrode separation trench 36. The first white reflection material 19 is located at the transparent electrode separation trench 31 side when viewed from the cell connection trench 32 and corresponds to the first white reflection material 16 in Embodiment 1. While the first white reflection material 19, basically similar to the case described in Embodiment 1, is configured with white insulation material, the material is configured with multi-layers whose white pigment concentration is progressively-increasing from the light receiving side. That is, in Embodiment 3, the first white reflection material 19 contacting one side surface of the photoelectric conversion layer 4 is formed, in the separation trench 36 of the transparent electrode 2 between the adjacent cells, as a light scattering layer whose white concentration varies.

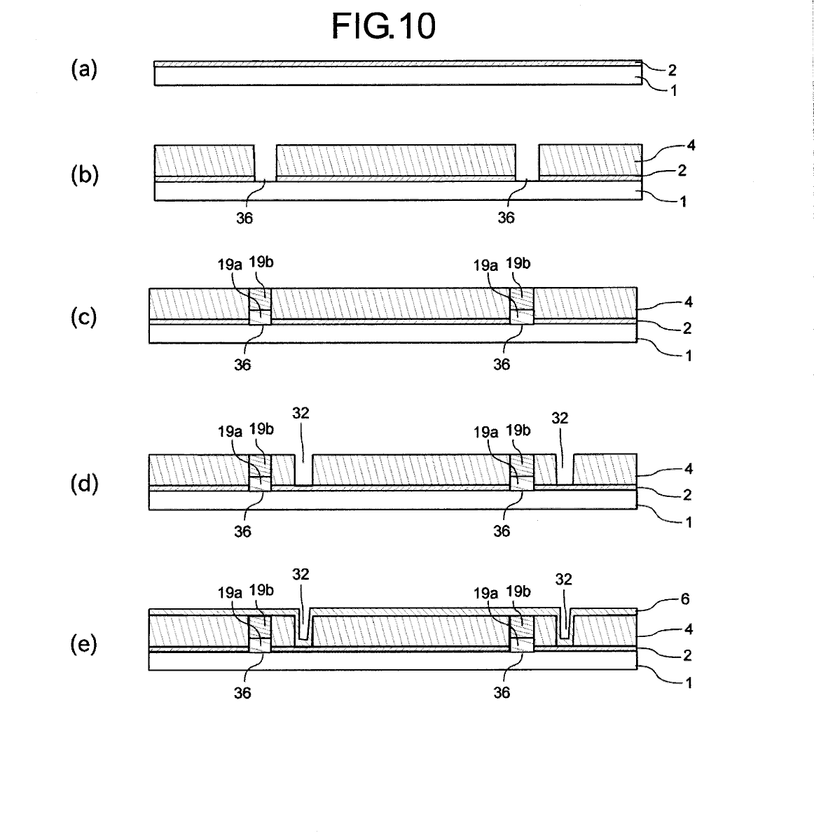

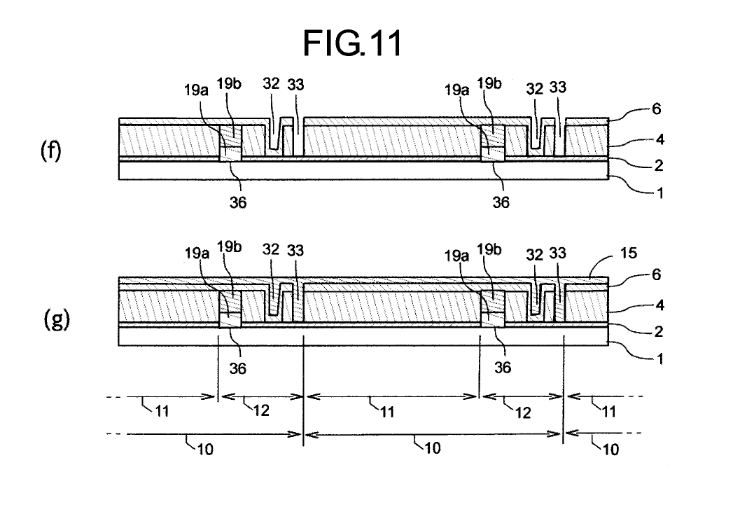

Next, a manufacturing method of the thin film solar cell module according to Embodiment 3 is described. FIG. 10(a)-(e) and FIG. 11(f)-(g) are partial cross sectional views illustrating the manufacturing method of the thin film solar cell module according to Embodiment 3. First, as shown in FIG. 10(a), the transparent electrode 2 is formed on the translucent insulation substrate 1 in Process A. Unlike Embodiment 1, etc., Process B for separating the transparent electrode 2 between the cells is not executed at this stage.

After that, similarly to Embodiment 1, etc., Process C is executed to stack the photoelectric conversion layer 4 consisting of a thin film semiconductor layer on the transparent electrode 2. Further, as shown in FIG. 10(b), the separation trench 36 is formed by concurrently ablating the transparent electrode 2 and the photoelectric conversion layer 4 with a laser scribing method, etc. In order to concurrently process the transparent electrode 2 and the photoelectric conversion layer 4 with a laser scribing method, it may be helpful to use a fundamental harmonic of a YAG laser. The separation trench 36, which is a trench to separate the transparent electrode, is formed along the longitudinal direction of the cell 10. The bottom portion of the separation trench 36 is the translucent insulation substrate 1. The separation trench 36 also serves as a trench to separate the photoelectric conversion layer 4, similar to the first separation trench 34 in Embodiment 1. That is, there are concurrently executed Process B for forming the transparent electrode separation trench to separate the transparent electrode 2 between the cells and Process H for forming the first separation trench, in which the photoelectric conversion layer is removed, between the cell connection trench 32 and the transparent electrode separation trench.

And then, as shown in FIG. 10(c), Process I is executed to fill the separation trench 36 with white insulation material. In order for the white reflectance to become larger gradually from the translucent insulation substrate 1 side toward the rear surface electrode 6 side, white insulation material is used to form a multilayer whose white pigment concentration is progressively-increasing toward the rear surface side. The pigment concentration is mass proportion of the pigment component contained in the paint, and is determined by proportion of the pigment component contained in the white paint to be coated. The white pigment concentration at the translucent insulation substrate 1 side is lower than the white pigment concentration at the rear surface electrode 6 side.

The figure shows a case in which white reflection material 19a having a lower pigment concentration and white reflection material 19b having a higher pigment concentration are formed into two layers as the first white reflection material 19. The number of layers whose concentrations differ may be more than two, or a concentration gradient layer having no explicit boundary of layers may be employed. As shown in the figure, it is preferable that the thickness of the white reflection material 19a having a lower pigment concentration is larger than the thickness of the transparent electrode 2. Such a difference in concentration can achieve lower reflectance at the light receiving surface side and higher reflectance at the rear surface side. Since white pigment particles are dispersed into the transparent resin in the white insulation material, the optical transmittance is high, which is semi-transparent, at the translucent insulation substrate 1 side which is the light receiving surface, and is low at the rear surface electrode 6 side. For example, while 1-20 parts by mass of white pigment particles may be contained per 100 parts by mass of resin configuring the white paint film of the white reflection material 19a, the white reflection material 19b of the rear surface side may contain 21-200 parts by mass of white pigment particles. The pigment concentration of the white reflection material located nearest to the light receiving side may be no more than 1/100-⅕ of the pigment concentration of the white reflection material located nearest to the rear surface side.

Local coating of the trench with the white paint can be executed by a method of using dispenser, inkjet, or screen printing. By stacking a plurality of layers whose concentrations differ, the concentration gradient described above may be configured. Although it is illustrated in the figure that the separation trench 36 is completely filled with the first white reflection material 19, the trench is not necessarily completely filled as long as the bottom surface of the separation trench 36, the side surface of the transparent electrode 2, and part of the side surface of the photoelectric conversion layer 4 are coated. At the coating, the first white reflection material 19 may partially run off the edge of the separation trench 36 on the neighboring area of the transparent electrode 2. Thus, only the inside of the trench, or the trench and its neighboring area is coated locally with the first white reflection material 19, so that the top portion of the photoelectric conversion layer 4 is scarcely covered.

Next, the subsequent processes are similar to those in Embodiment 1, that is, after executing Process D for forming the cell connection trench 32 as shown in FIG. 10(d), Process E and Process F are executed, as shown in FIG. 10(e), to form the rear surface electrode 6 by forming the metal film so as to cover the entire top surface of the photoelectric conversion layer 4 and the inside of the cell connection trench 32. After that, as shown in FIG. 11(f), Process G and Process J are executed to form the rear surface electrode separation trench 33 for separating the rear surface electrode 6 and the photoelectric conversion layer 4 between the cells. And finally, as shown in FIG. 11(g), Process K is executed to form the second white reflection material 15 in the rear surface electrode separation trench 33.

While the figure shows a case in which single-concentration white reflection material is used as the second white reflection material 15, the second white reflection material 15 may be formed, similar to the first white reflection material 19, with its white pigment content varied.

In Embodiment 3 as described above, the first and second white reflection materials 19 and 15 containing the white insulation material are formed in the neighboring areas on both sides of the cell connection trench 32. That is, surfaces of diffusely reflecting light are provided at both side surfaces of the power generation area 11 of the cell in its longitudinal direction, and also incident light to the transparent electrode separation trench portion of the separation trench 36 corresponding to the transparent electrode separation trench can be used as scattered light at the inside of the cell.

For the first white reflection layer 19, at least its portion whose thickness is larger than that of the transparent electrode 2 located just above the translucent insulation substrate 1 is better to have optical transparency by using the white reflection material 19a having a low pigment concentration. In Embodiment 3, although the first white reflection material 19 is protruded toward the light incident side beyond the photoelectric conversion layer 4 because the bottom portion of the separation trench 36 reaches the translucent insulation substrate 1, optical transparency is given to the portion corresponding to the thickness of the transparent electrode 2, therefore the protruded portion does not completely intercept incident light entering the photoelectric conversion layer 4 even when it enters at an angle, thereby improving light use efficiency. For the optical transparency, it is preferable to set attenuation of visible light passing through the layer corresponding to the thickness of the white reflection material 19a to be no more than ½. In Embodiment 3, while a small amount of white pigments are contained so that the white reflection material 19a has both optical transparency and light-scattering property, a completely transparent layer without containing the white pigment may be employed when the optical transparency is more important. When making the thickness of the white reflection material 19a substantially equal to that of the transparent electrode 2, a transparent resin layer scarcely containing the white pigment may be employed in place of the white reflection material 19a. In this case, resin material, for example, same with that contained in the white reflection material 19b may be used.

Because insulation layers are formed not only on both sides of the cell connection trench 32 but also at the inside of the trench between the transparent electrodes, it is possible to inhibit transverse leakage of the current, which is generated in the power generation area 11, via conductive material formed on the side surface of the photoelectric conversion layer 4 in the cell connection trench 32, and transverse leakage between the adjacent transparent electrode portions, thereby preventing conversion efficiency deterioration.

While the first white reflection material 19 whose concentration varies is formed in the separation trench 36 in the above, the white reflection material 15 at the inside of the rear surface electrode separation trench 33 may also have a varying concentration. For example, adhesive strength of the white reflection material 15 may be enhanced by forming the white reflection material 15 after forming a thin semitransparent layer having a low white pigment concentration and high adhesive strength. Also in Embodiment 2, a structure in which the white concentration varies may be similarly employed.

Part of the configuration described in any one of the above embodiments may be replaced by or combined with other embodiment if there is no technical inconsistency. Also, the effects may be obtained even when part of components is missing. While the white reflection material for light containing the white insulation material is provided in the present invention so as to improve the efficiency by reusing the light passing through between the cells toward the back, a transparent or opaque resin layer without containing the pigment may be provided in place of the white reflection material in the configuration or the manufacturing method of the thin film solar cell module, for example, according to Embodiment 2. In this case, a thin film solar cell module is also obtained which is easy to manufacture and has high efficiency by narrowing the connection area 12 and inhibiting the leakage.

### INDUSTRIAL APPLICABILITY

In the present invention, a high-performance thin film solar cell module can be achieved, and manufacturing the same can be facilitated.

Reference Numerals

1: translucent insulation substrate; 2: transparent electrode; 4:

photoelectric conversion layer; 6: rear surface electrode; 6a: first rear surface electrode; 6b: second rear surface electrode; 10: unit solar cell (cell); 11: power generation area; 12: connection area; 15: second white reflection material; 16: first white reflection material; 17: white reflection material; 19: first white reflection material; 31: transparent electrode separation trench; 32: cell connection trench; 33: rear surface electrode separation trench (second separation trench); 34: first photoelectric conversion layer separation trench (first separation trench); and 35,36: separation trenches.

1. A thin film solar cell module arranged with a plurality of cells in which a transparent electrode, a photoelectric conversion layer, and a rear surface electrode are stacked in this order on a translucent insulation substrate, the thin film solar cell module comprising, between adjacent cells:
a transparent electrode separation trench for separating the transparent electrode between the cells;
a rear surface electrode separation trench for separating the rear surface electrode between the cells; and
a cell connection apertural area, located between the transparent electrode separation trench and the rear surface electrode separation trench, for electrically connecting the rear surface electrode of one of the cells and the transparent electrode of another of the cells; wherein
photoelectric conversion layer separation trenches in which the photoelectric conversion layer is removed are provided between the cell connection apertural area and the transparent electrode separation trench and in an area from the cell connection apertural area through the rear surface electrode separation trench; and
white reflection material having an insulation property is formed at the inside of the photoelectric conversion layer separation trench.

2. The thin film solar cell module according to claim 1, wherein
only a single separation trench for separating the photoelectric conversion layer is provided between the adjacent cells;
the white reflection material is formed in the separation trench; and
an apertural area for electrically connecting the adjacent cells and the rear surface electrode separation trench are formed in the white reflection material.

3. The thin film solar cell module according to claim 1, wherein
the white reflection material contains white pigment; and
a concentration of the white pigment on the translucent insulation substrate side is lower than a concentration of the white pigment on the rear surface electrode side.

4. The thin film solar cell module according to claim 1, wherein
the photoelectric conversion layer separation trench in which the photoelectric conversion layer is removed between the cell connection apertural area and the transparent electrode separation trench is a separation trench for separating the photoelectric conversion layer along with the transparent electrode;
the white reflection material formed in the separation trench contains white pigment;
a concentration of the white pigment on the translucent insulation substrate side is lower than a concentration of the white pigment on the rear surface electrode side; and
a portion thicker than a thickness of the transparent electrode located just above the translucent insulation substrate is optically transparent.

5. A method of manufacturing a thin film solar cell module arranged with a plurality of cells in which a transparent electrode, a photoelectric conversion layer, and a rear surface electrode are stacked in this order, the method comprising:
Process A for forming a transparent electrode on a translucent insulation substrate;
Process B for forming a transparent electrode separation trench to separate the transparent electrode between the cells;
Process C for forming a photoelectric conversion layer on the transparent electrode;
Process D for forming a cell connection apertural area in which the photoelectric conversion layer is removed and whose bottom portion reaches the transparent electrode;
Process E for forming a rear surface electrode on the photoelectric conversion layer;
Process F for electrically connecting the rear surface electrode of one of the cells and the transparent electrode of another of the cells at the inside of the cell connection apertural area;
Process G for forming a rear surface electrode separation trench to separate the rear surface electrode between the cells;
Process H for forming, in an area from the cell connection apertural area through the transparent electrode separation trench, a first photoelectric conversion layer separation trench in which the photoelectric conversion layer is removed;
Process I for forming white reflection material by coating paint containing white pigment in the first photoelectric conversion layer separation trench formed in Process H;
Process J for forming, in an area from the cell connection apertural area through the rear surface electrode separation trench, a second photoelectric conversion layer separation trench in which the photoelectric conversion layer is removed; and
Process K for forming white reflection material by coating paint containing white pigment in the second photoelectric conversion layer separation trench formed in Process J.

6. The method of manufacturing the thin film solar cell module according to claim 5, wherein
Process H and Process J are concurrently executed, after Process A, Process B, and Process C, by forming, between the cells, one combined photoelectric conversion layer separation trench which serves as the first photoelectric conversion layer separation trench and the second photoelectric conversion layer separation trench;
Process I and Process K are concurrently executed by forming the white reflection material in the one combined photoelectric conversion layer separation trench between the cells;
Process D is executed, after Process I and Process K, to form the cell connection apertural area by removing part of the white reflection material;
Process E and Process F are executed after Process D; and
Process G is a process for removing a portion of the white reflection material and the rear surface electrode on the portion of the white reflection material.

7. The method of manufacturing the thin film solar cell module according to claim 6, wherein the white reflection material formed in Process I and Process K contains polyimide resin; and
a removing method of irradiating a laser beam having a wavelength of 400-450 nm is employed to remove the white reflection material in Process D or Process G.

8. The method of manufacturing the thin film solar cell module according to claim 5, wherein
a combined trench which works as the transparent electrode separation trench and the first photoelectric conversion layer separation trench is formed by concurrently executing Process B and Process H; and
a concentration of the white pigment of the white reflection material on the translucent insulation substrate side is lower than a concentration of the white pigment on the rear surface electrode side by stacking in the trench, in Process I, white paint whose concentration of the white pigment varies.
